(19) United States
(12) Patent Application Publication
(10) Pub. No.: US 2022/0067229 A1
(43) Pub. Date: Mar. 3, 2022

(54) DIGITAL TWIN MULTI-DIMENSIONAL MODEL RECORD USING PHOTOGRAMMETRY

(71) Applicant: International Business Machines Corporation, Armonk, NY (US)

(72) Inventor: John Kaufmann, Austin, TX (US)

(21) Appl. No.: 17/011,413

(22) Filed: Sep. 3, 2020

(51) Int. Cl. G06F 30/13

(52) U.S. Cl. CPC G06F 30/13

(57) ABSTRACT

In an approach to constructing a digital twin multi-dimensional model record using photogrammetry, a plurality of images of an asset are received from one or more mobile devices. A 3D model of the asset is constructed from the plurality of images. If the 3D model of the asset matches a digital twin record is determined.

### BACKGROUND

The present invention relates generally to the field of data processing, and more particularly to constructing a digital twin multi-dimensional model record using photogrammetry.

A digital twin is a virtual representation of a physical object or system across its life-cycle. It uses real-time data and other sources to enable learning, reasoning, and dynamically recalibrating for improved decision making. Simply, this means creating a highly complex virtual model that is the exact counterpart (or twin) of a physical thing. The ‘thing’ could be a car, a tunnel, a bridge, or even a jet engine. Connected sensors on the physical asset collect data that can be mapped onto the virtual model. By viewing the digital twin, a user can now see crucial information about how the physical thing is operating in the real world.

Photogrammetry is defined as the art, science, and technology of obtaining reliable information about physical objects and the environment through the process of recording, measuring, and interpreting photographic images. Photogrammetry makes precise measurements of three-dimensional objects and terrain features from two-dimensional photographs. Applications include the measuring of coordinates, quantification of distances, heights, areas, and volumes, 3D topographic mapping, and the generation of digital elevation models and orthophotographs.

### SUMMARY

Embodiments of the present invention disclose a method, a computer program product, and a system for constructing a digital twin multi-dimensional model record using photogrammetry. In one embodiment, a plurality of images of an asset are received from one or more mobile devices. A 3D model of the asset is constructed from the plurality of images. If the 3D model of the asset matches a digital twin record is determined.

### BRIEF DESCRIPTION OF THE DRAWINGS

FIG. 1 is a functional block diagram illustrating a distributed data processing environment, in accordance with an embodiment of the present invention.

FIG. 2a is an example of a user of the photogrammetry program using a device to capture photographs of an object, in accordance with an embodiment of the present invention.

FIG. 2b is an example of a 3D model constructed by the photogrammetry program, in accordance with an embodiment of the present invention.

FIG. 2c is an example of the photogrammetry program matching the 3D model to a digital twin, in accordance with an embodiment of the present invention.

FIG. 3 is a flowchart depicting operational steps of the photogrammetry program, on a computing device within the distributed data processing environment of FIG. 1, for constructing a digital twin multi-dimensional model record using photogrammetry, in accordance with an embodiment of the present invention.

FIG. 4 depicts a block diagram of components of the computing device executing the photogrammetry program within the distributed data processing environment of FIG. 1, in accordance with an embodiment of the present invention.

### DETAILED DESCRIPTION

Photogrammetry, as used here, is the technique of taking multiple overlapping photographs and deriving measurements from the photographs to create three-dimensional (3D) models of objects or scenes. The basic principle is similar to the ability many cameras have that allow a user to create a panorama by stitching together overlapping photographs into a two-dimensional (2D) mosaic. Photogrammetry takes the concept one step further by using the position of the camera as it moves through 3D space to estimate X, Y and Z coordinates for each pixel of the original image.

A digital twin is a virtual model of a process, product, or service. This pairing of the virtual and physical worlds allows analysis of data and monitoring of systems to head off problems before they even occur, prevent downtime, develop new opportunities and even plan for the future by using simulations. For example, a digital twin of an Internet of Things (IoT) device provides both the elements and the dynamics of how the device operates and lives throughout its life cycle.

Digital twins can integrate IoT, artificial intelligence, machine learning and software analytics to create living digital simulation models that update and change as their physical counterparts change. A digital twin continuously learns and updates itself from multiple sources to represent its near real-time status, working condition or position. A digital twin also integrates historical data from past machine usage to factor into its digital model.

The present invention allows digital twin owners to produce an immutable record of 3D models of their physical assets using any mobile device outfitted with a camera input and apply them to their associated digital twins from a digital twin library or repository, or to create new digital twins from the 3D models created from the photographs that are added to the repository. This data can then be used for any of the forms of analysis mentioned above.

In an embodiment, the immutable model data is input into an asset management system. In an embodiment, the present invention uses blockchain technology to store the model in a digital twin library or repository, to input the model into the asset management system, or to share the immutable model data records with different parties.

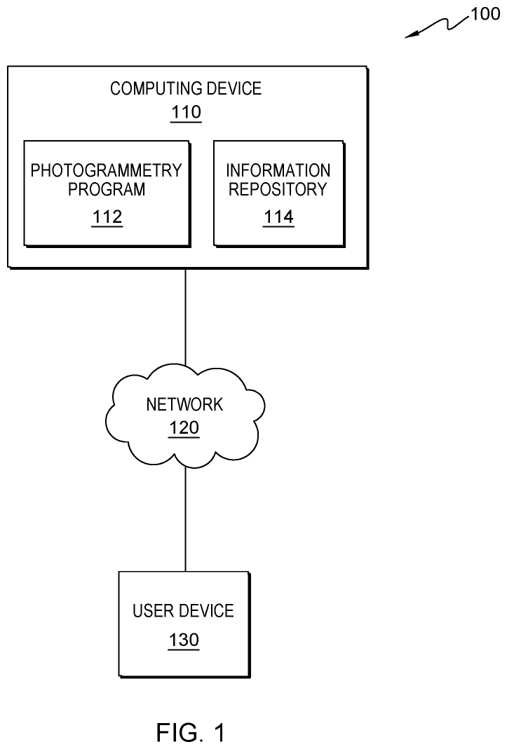

FIG. 1 is a functional block diagram illustrating a distributed data processing environment, generally designated 100, suitable for operation of photogrammetry program 112 in accordance with at least one embodiment of the present invention. The term “distributed” as used herein describes a computer system that includes multiple, physically distinct devices that operate together as a single computer system. FIG. 1 provides only an illustration of one implementation and does not imply any limitations with regard to the environments in which different embodiments may be implemented. Many modifications to the depicted environment may be made by those skilled in the art without departing from the scope of the invention as recited by the claims.

Distributed data processing environment 100 includes computing device 110 and user device 130, both connected to network 120. Network 120 can be, for example, a telecommunications network, a local area network (LAN), a wide area network (WAN), such as the Internet, or a combination of the three, and can include wired, wireless, or fiber optic connections. Network 120 can include one or more wired and/or wireless networks that are capable of receiving and transmitting data, voice, and/or video signals, including multimedia signals that include voice, data, and video information. In general, network 120 can be any combination of connections and protocols that will support communications between computing device 110, user device 130, and other computing devices (not shown) within distributed data processing environment 100.

Computing device 110 can be a standalone computing device, a management server, a web server, a mobile computing device, or any other electronic device or computing system capable of receiving, sending, and processing data. In an embodiment, computing device 110 can be a laptop computer, a tablet computer, a netbook computer, a personal computer (PC), a desktop computer, a personal digital assistant (PDA), a smart phone, or any programmable electronic device capable of communicating with other computing devices (not shown) within distributed data processing environment 100 via network 120. In another embodiment, computing device 110 can represent a server computing system utilizing multiple computers as a server system, such as in a cloud computing environment. In yet another embodiment, computing device 110 represents a computing system utilizing clustered computers and components (e.g., database server computers, application server computers, etc.) that act as a single pool of seamless resources when accessed within distributed data processing environment 100.

In an embodiment, computing device 110 includes photogrammetry program 112. In an embodiment, photogrammetry program 112 is a program, application, or subprogram of a larger program for constructing a digital twin multi-dimensional model record using photogrammetry. In an alternative embodiment, photogrammetry program 112 may be located on any other device accessible by computing device 110 via network 120.

In an embodiment, computing device 110 includes information repository 114. In an embodiment, information repository 114 may be managed by photogrammetry program 112. In an alternate embodiment, information repository 114 may be managed by the operating system of the device, alone, or together with, photogrammetry program 112. Information repository 114 is a data repository that can store, gather, compare, and/or combine information. In some embodiments, information repository 114 is located externally to computing device 110 and accessed through a communication network, such as network 120. In some embodiments, information repository 114 is stored on computing device 110. In some embodiments, information repository 114 may reside on another computing device (not shown), provided that information repository 114 is accessible by computing device 110. Information repository 114 includes, but is not limited to, photographic image data, digital twin data, 3D modeling data, system data, user data, and other data that is received by photogrammetry program 112 from one or more sources, and data that is created by photogrammetry program 112.

In an embodiment, information repository 114 may also contain a digital twin repository. In an embodiment, the digital twin repository may be separate from information repository 114, provided that the digital twin repository is accessible by computing device 110.

Information repository 114 may be implemented using any volatile or non-volatile storage media for storing information, as known in the art. For example, information repository 114 may be implemented with a tape library, optical library, one or more independent hard disk drives, multiple hard disk drives in a redundant array of independent disks (RAID), solid-state drives (SSD), or random-access memory (RAM). Similarly, information repository 114 may be implemented with any suitable storage architecture known in the art, such as a relational database, a NoSQL database, an object-oriented database, or one or more tables.

User device 130 can be a smart phone, standalone computing devices, a mobile computing device, or any other electronic device or computing system that includes the ability to capture photographic images and is capable of receiving, sending, and processing data. In an embodiment, user device 130 can be a smart phone, a laptop computer, a tablet computer, a netbook computer, a personal computer (PC), a desktop computer, a personal digital assistant (PDA), or any programmable electronic device that includes the ability to capture photographic images and is capable of communicating with other computing devices (not shown) within distributed data processing environment 100 via network 120.

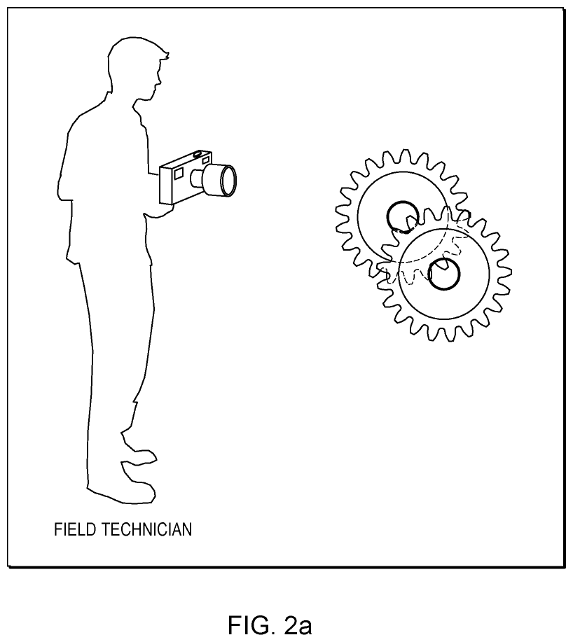

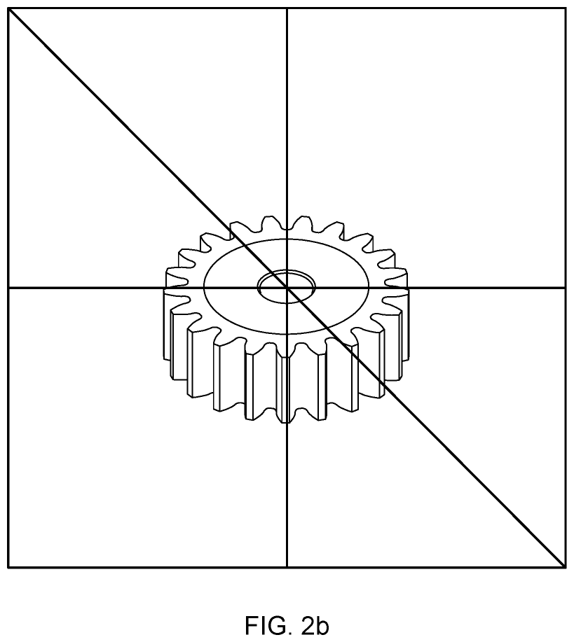

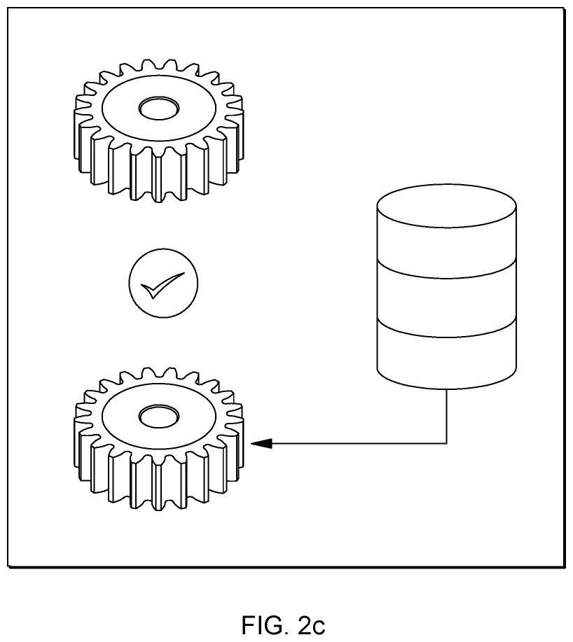

FIGS. 2a-2c are an example of constructing a digital twin multi-dimensional model record using photogrammetry, as performed by photogrammetry program 112 in accordance with an embodiment of the present invention. In FIG. 2a, a user of photogrammetry program 112 uses a device containing a camera, e.g., user device 130 from FIG. 1, to capture standard 2D photographs of an object, for example, a piece of industrial machinery, that photogrammetry program 112 will use to construct a 3D model. In FIG. 2b, photogrammetry program 112 is constructing a 3D model from the 2D photographs captured by the user. Once all the images are captured and the 3D model has been constructed, in FIG. 2c photogrammetry program 112 matches the 3D model created in FIG. 2b to a digital twin kept on record in a digital twin repository. In this example, the user wants to generate and keep records of frequently used machinery. By using a mobile device, such as a smart phone, the user can create new or updated digital twin models of the equipment at regular intervals, e.g., every two months, or after certain events, such as equipment upgrades or periods of heavy use. This allows the digital twin to accurately reflect the actual equipment throughout its life cycle.

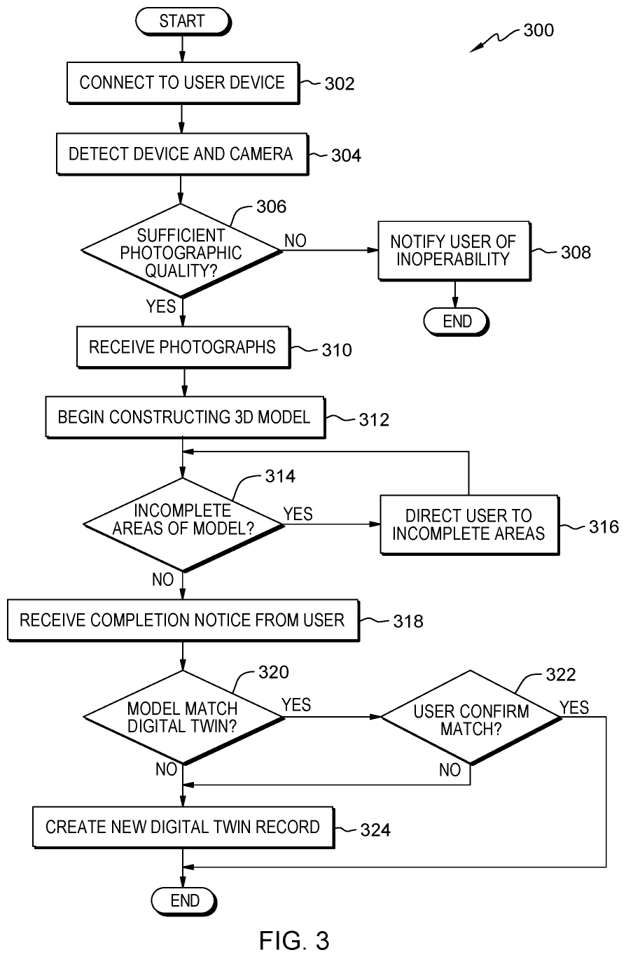

FIG. 3 is a flow chart diagram of workflow 300 depicting operational steps for photogrammetry program 112 for constructing a digital twin multi-dimensional model record using photogrammetry in accordance with at least one embodiment of the invention. In an alternative embodiment, the steps of workflow 300 may be performed by any other program while working with photogrammetry program 112. In an embodiment, photogrammetry program 112 connects to a user device to begin constructing the 3D model. In an embodiment, photogrammetry program 112 detects the specific device. In an embodiment, photogrammetry program 112 determines if the detected camera meets a threshold for quality metrics for photographs for calibration of the algorithm to construct the 3D model. In an embodiment, if photogrammetry program 112 determines that the camera does not meet a threshold for quality metrics, then photogrammetry program 112 notifies the user that the camera is inoperable for the construction of a digital twin multi-dimensional model record using photogrammetry. Photogrammetry program 112 then ends for this cycle. In an embodiment, photogrammetry program 112 receives a series of 2D photographs from the camera in the device. In an embodiment, photogrammetry program 112 begins to construct a 3D model using the 2D photographs received in the previous step. In an embodiment, photogrammetry program 112 determines if there are areas of the 3D model that are incomplete or inaccurate. In an embodiment, if photogrammetry program 112 determines that there are areas of the 3D model that are incomplete or inaccurate, then photogrammetry program 112 directs the user to the incomplete areas to capture additional photographs. In an embodiment, when the user has completed taking photographs of the item, photogrammetry program 112 receives a completion notice from the user. In an embodiment, photogrammetry program 112 determines if the constructed 3D model matches a digital twin by comparing the 3D model to all digital twins in a repository. In an embodiment, if photogrammetry program 112 determines that the constructed 3D model does match a digital twin, then photogrammetry program 112 determines if the user confirms a match. In an embodiment, if photogrammetry program 112 determines that the constructed 3D model does not match a digital twin, or that the user does not confirm a match, then photogrammetry program 112 creates a new digital twin from the constructed 3D model. In an embodiment, photogrammetry program 112 then creates a new record in the repository and stores the new digital twin in the record.

It should be appreciated that embodiments of the present invention provide at least for constructing a digital twin multi-dimensional model record using photogrammetry. However, FIG. 3 provides only an illustration of one implementation and does not imply any limitations with regard to the environments in which different embodiments may be implemented. Many modifications to the depicted environment may be made by those skilled in the art without departing from the scope of the invention as recited by the claims.

Photogrammetry program 112 connects to a user device (step 302). In an embodiment, photogrammetry program 112 connects to a user device, e.g., user device 130 from FIG. 1, to begin constructing the 3D model. In an embodiment, photogrammetry program 112 connects to the user device based on receiving a request from the user to connect. In another embodiment, photogrammetry program 112 connects to the user device automatically upon the user starting a camera app on the device. In an embodiment, photogrammetry program 112 maintains the connection between the user device and the computing device throughout the process of capturing the image data. In an embodiment, photogrammetry program 112 connects to a user device over a network, e.g., network 120 from FIG. 1.

Photogrammetry program 112 detects the device and camera (step 304). In an embodiment, photogrammetry program 112 detects the specific device connected to in step 302. In an embodiment, photogrammetry program 112 detects the camera in the user device. In an embodiment, photogrammetry program 112 uses a database of imaging devices to detect the specific device. In another embodiment, photogrammetry program 112 probes the device for camera specifications. In yet another embodiment, photogrammetry program 112 receives the device specifications from the user.

Photogrammetry program 112 determines if the camera has sufficient photographic quality (decision block 306). In an embodiment, photogrammetry program 112 determines if the camera detected in step 304 meets a threshold for quality metrics for photographs for calibration of the algorithm to construct the 3D model. In an embodiment, the quality metrics for photographs may include image resolution, sharpness, dynamic range, distortion, and noise. In another embodiment, the quality metrics for photographs may include the sensitivity to light of the image sensor, the angle between the camera and the object, and whether the background is monochromatic (i.e., a monochromatic background may make edge detection more difficult).

In an embodiment, if photogrammetry program 112 determines that the camera meets a threshold for quality metrics (“yes” branch, decision block 306), then photogrammetry program 112 proceeds to step 310.

Photogrammetry program 112 notifies the user of inoperability (step 308). In an embodiment, if photogrammetry program 112 determines that the camera does not meet a threshold for quality metrics (“no” branch, decision block 306), then photogrammetry program 112 notifies the user that the camera is inoperable for the construction of a digital twin multi-dimensional model record using photogrammetry. Photogrammetry program 112 then ends for this cycle.

Photogrammetry program 112 receives photographs (step 310). In an embodiment, if photogrammetry program 112 determines that the camera does meet a threshold for quality metrics (“yes” branch, decision block 306), then photogrammetry program 112 receives a series of 2D photographs from the camera in the device. In an embodiment, photogrammetry program 112 receives images in the Joint Photographic Experts Group (JPEG) format. In other embodiments, photogrammetry program 112 may receive images in camera raw format, Tagged Image File Format (TIFF), or any other digital format for 2D photographs as would be known to a person of skill in the art. In an embodiment, the photographs are received over a network, e.g., network 120 from FIG. 1.

Photogrammetry program 112 begins constructing a 3D model (step 312). In an embodiment, photogrammetry program 112 begins to construct a 3D model using the 2D photographs received in step 310. In an embodiment, photogrammetry program 112 continuously monitors the completeness and accuracy of the generated model based on the input photographs. In an embodiment, photogrammetry program 112 the scale-invariant feature transform (SIFT) algorithm to begin constructing the 3D model. In another embodiment, photogrammetry program 112 uses the Gradient Location and Orientation Histogram (GLOH) algorithm to begin constructing the 3D model. In yet another embodiment, photogrammetry program 112 uses any 2D to 3D construction algorithm as would be known to a person of skill in the art to begin constructing the 3D model.

Photogrammetry program 112 determines if there are incomplete areas of the model (decision block 314). In an embodiment, photogrammetry program 112 determines if there are areas of the 3D model that are incomplete or inaccurate. In an embodiment, photogrammetry program 112 determines completeness and accuracy of the model based on differences between the photographs. For example, if photogrammetry program 112 determines to add detail to one area of the model from an incoming photograph, another photograph from that area and angle will be required to compare against the last computations. In an embodiment, photogrammetry program 112 determines completeness and accuracy of the model based on the 3D factor. For example, some models might only be able to build 70% of the model due to placement in the machine (e.g., you can only take photos of the front and sides of a wheel as the back is connected into the axle). In this example, as the 3D model is matched to the digital twin, the fact that only 70% of the model was constructed will be taken into determination of the overall completeness of the 3D model.

Photogrammetry program 112 directs the user to incomplete areas (step 316). In an embodiment, if photogrammetry program 112 determines that there are areas of the 3D model that are incomplete or inaccurate, (“yes” branch, decision block 314), then photogrammetry program 112 directs the user to the incomplete areas to capture additional photographs. In an embodiment, photogrammetry program 112 directs the user to the incomplete areas to capture additional photographs by sending movement instructions to the user device. For example, photogrammetry program 112 may send an arrow to the screen of the user device to indicate to the user the direction the user should move to capture more images. In another embodiment, photogrammetry program 112 directs the user to the incomplete areas to capture additional photographs by sending one of the earlier photographs to the user device with the incomplete areas highlighted. In yet another embodiment, photogrammetry program 112 directs the user to the incomplete areas to capture additional photographs using any appropriate notification method as would be known to a person of skill in the art.

Photogrammetry program 112 receives a completion notice from the user (step 318). In an embodiment, when the user has completed taking photographs of the item, photogrammetry program 112 receives a completion notice from the user. In an embodiment, this notice signals photogrammetry program 112 that no further photographs will be received, and therefore construction of the 3D model is complete.

Photogrammetry program 112 determines if the model matches a digital twin (decision block 320). In an embodiment, photogrammetry program 112 determines if the constructed 3D model matches a digital twin by comparing the 3D model to all digital twins in a repository. In an embodiment, photogrammetry program 112 determines if the constructed 3D model matches a digital twin based on model properties and metadata of the photographs. In an embodiment, if photogrammetry program 112 determines that the constructed 3D model does not match a digital twin, (“no” branch, decision block 320), then photogrammetry program 112 proceeds to step 324 to create a new record.

In an embodiment, photogrammetry program 112 determines if the constructed 3D model matches a digital twin based on using the 3D point vectors and comparing the nearest points of other digital twins based on each photograph. For example, one photograph is received with a generated set of 3D points, and the database is searched for the closest match. In an embodiment, this process is continued as the model continues to be built.

Photogrammetry program 112 determines if the user confirms a match (decision block 322). In an embodiment, if photogrammetry program 112 determines that the constructed 3D model does match a digital twin, (“yes” branch, decision block 320), then photogrammetry program 112 determines if the user confirms a match. In an embodiment, if photogrammetry program 112 determines that the user does not confirms a match, (“no” branch, decision block 322), then photogrammetry program 112 proceeds to step 324. In an embodiment, photogrammetry program 112 requests a confirmation from the user that the constructed 3D model and the digital twin from the repository match. In an embodiment, photogrammetry program 112 sends a copy of the digital twin to the user device to allow the user to confirm that the constructed 3D model matches the digital twin from the repository. In another embodiment, photogrammetry program 112 sends a link to the copy of the digital twin to the user device to allow the user to view the digital twin and confirm that the constructed 3D model and the digital twin from the repository match. Photogrammetry program 112 then ends for this cycle.

Photogrammetry program 112 creates a new digital twin record (step 324). In an embodiment, if photogrammetry program 112 determines that the constructed 3D model does not match a digital twin, (“no” branch, decision block 320), or that the user does not confirm a match, (“no” branch, decision block 322), then photogrammetry program 112 creates a new digital twin from the constructed 3D model. In an embodiment, photogrammetry program 112 constructs the physical portion of the digital twin from the 3D model. In an embodiment, photogrammetry program 112 then creates a new record in the repository and stores the new digital twin in the record. In an embodiment, photogrammetry program 112 then gathers additional data about the object, for example, IoT sensor data, operational data, simulation data, etc., about the object from the user. In an embodiment, photogrammetry program 112 then adds the additional data to the digital twin. Photogrammetry program 112 then ends for this cycle.

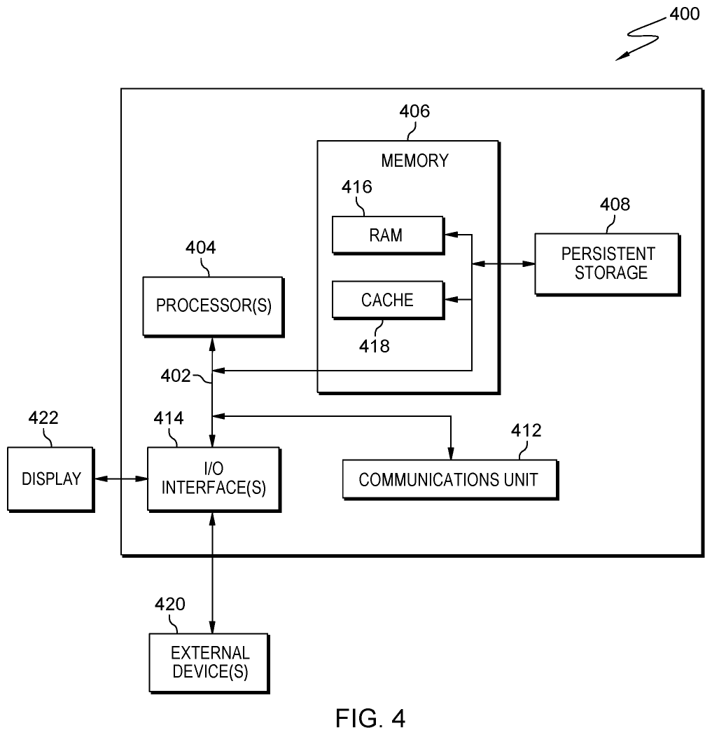

FIG. 4 is a block diagram depicting components of computing device 110 suitable for photogrammetry program 112, in accordance with at least one embodiment of the invention. FIG. 4 displays the computer 400, one or more processor(s) 404 (including one or more computer processors), a communications fabric 402, a memory 406 including a random-access memory (RAM) 416 and a cache 418, a persistent storage 408, a communications unit 412, I/O interfaces 414, a display 422, and external devices 420. It should be appreciated that FIG. 4 provides only an illustration of one embodiment and does not imply any limitations with regard to the environments in which different embodiments may be implemented. Many modifications to the depicted environment may be made by those skilled in the art.

As depicted, the computer 400 operates over the communications fabric 402, which provides communications between the computer processor(s) 404, memory 406, persistent storage 408, communications unit 412, and input/output (I/O) interface(s) 414. The communications fabric 402 may be implemented with any architecture suitable for passing data or control information between the processors 404 (e.g., microprocessors, communications processors, and network processors), the memory 406, the external devices 420, and any other hardware components within a system. For example, the communications fabric 402 may be implemented with one or more buses.

The memory 406 and persistent storage 408 are computer readable storage media. In the depicted embodiment, the memory 406 comprises a RAM 416 and a cache 418. In general, the memory 406 can include any suitable volatile or non-volatile computer readable storage media. Cache 418 is a fast memory that enhances the performance of processor(s) 404 by holding recently accessed data, and near recently accessed data, from RAM 416.

Program instructions for photogrammetry program 112 may be stored in the persistent storage 408, or more generally, any computer readable storage media, for execution by one or more of the respective computer processors 404 via one or more memories of the memory 406. The persistent storage 408 may be a magnetic hard disk drive, a solid-state disk drive, a semiconductor storage device, read only memory (ROM), electronically erasable programmable read-only memory (EEPROM), flash memory, or any other computer readable storage media that is capable of storing program instruction or digital information.

The media used by persistent storage 408 may also be removable. For example, a removable hard drive may be used for persistent storage 408. Other examples include optical and magnetic disks, thumb drives, and smart cards that are inserted into a drive for transfer onto another computer readable storage medium that is also part of persistent storage 408.

The communications unit 412, in these examples, provides for communications with other data processing systems or devices. In these examples, the communications unit 412 includes one or more network interface cards. The communications unit 412 may provide communications through the use of either or both physical and wireless communications links. In the context of some embodiments of the present invention, the source of the various input data may be physically remote to the computer 400 such that the input data may be received, and the output similarly transmitted via the communications unit 412.

The I/O interface(s) 414 allows for input and output of data with other devices that may be connected to computer 400. For example, the I/O interface(s) 414 may provide a connection to external device(s) 420 such as a keyboard, a keypad, a touch screen, a microphone, a digital camera, and/or some other suitable input device. External device(s) 420 can also include portable computer readable storage media such as, for example, thumb drives, portable optical or magnetic disks, and memory cards. Software and data used to practice embodiments of the present invention, e.g., photogrammetry program 112, can be stored on such portable computer readable storage media and can be loaded onto persistent storage 408 via the I/O interface(s) 414. I/O interface(s) 414 also connect to a display 422.

Display 422 provides a mechanism to display data to a user and may be, for example, a computer monitor. Display 422 can also function as a touchscreen, such as a display of a tablet computer.

The programs described herein are identified based upon the application for which they are implemented in a specific embodiment of the invention. However, it should be appreciated that any particular program nomenclature herein is used merely for convenience, and thus the invention should not be limited to use solely in any specific application identified and/or implied by such nomenclature.

The present invention may be a system, a method, and/or a computer program product. The computer program product may include a computer readable storage medium (or media) having computer readable program instructions thereon for causing a processor to carry out aspects of the present invention.

The computer readable storage medium can be any tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, a special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, a segment, or a portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A computer-implemented method for constructing a model, the computer-implemented method comprising:
receiving, by one or more computer processors, a plurality of images of an asset from one or more mobile devices;
constructing, by the one or more computer processors, a 3D model of the asset from the plurality of images; and
determining, by the one or more computer processors, whether the 3D model of the asset matches a digital twin record.

2. The computer-implemented method of claim 1, wherein determining whether the 3D model of the asset matches the digital twin record further comprises:
receiving, by the one or more computer processors, a confirmation from a user that the asset matches the digital twin record; and
associating, by the one or more computer processors, the 3D model of the asset with the digital twin record.

3. The computer-implemented method of claim 1, further comprising responsive to determining that the 3D model is incomplete, notifying, by the one or more computer processors, a user of the mobile device of one or more areas of the asset that require additional images.

4. The computer-implemented method of claim 1, wherein responsive to the 3D model of the asset does not match the digital twin record, creating, by the one or more computer processors, a new digital twin record for the 3D model.

5. The computer-implemented method of claim 1, further comprising utilizing, by the one or more computer processors, one or more photogrammetry techniques to construct the 3D model from the plurality of images.

6. The computer-implemented method of claim 1, wherein the 3D model is immutable.

7. The computer-implemented method of claim 1, wherein receiving the plurality of images of the asset from the one or more mobile devices further comprises receiving, by the one or more computer processors, a notification from a user of completion of the plurality of images.

8. A computer program product for constructing a model, the computer program product comprising:
one or more computer readable storage devices and program instructions stored on the one or more computer readable storage devices, the stored program instructions comprising instructions to:
receive a plurality of images of an asset from one or more mobile devices;
construct a 3D model of the asset from the plurality of images; and
determine whether the 3D model of the asset matches a digital twin record.

9. The computer program product of claim 8, wherein determining whether the 3D model of the asset matches the digital twin record further comprises one or more of the following program instructions, stored on the one or more computer readable storage media, to:
receive a confirmation from a user that the asset matches the digital twin record; and
associate the 3D model of the asset with the digital twin record.

10. The computer program product of claim 8, further comprising responsive to determining that the 3D model is incomplete, notify a user of the mobile device of one or more areas of the asset that require additional images.

11. The computer program product of claim 8, wherein responsive to the 3D model of the asset does not match the digital twin record, create a new digital twin record for the 3D model.

12. The computer program product of claim 8, further comprising utilize one or more photogrammetry techniques to construct the 3D model from the plurality of images.

13. The computer program product of claim 8, wherein the 3D model is immutable.

14. The computer program product of claim 8, wherein receive the plurality of images of the asset from the one or more mobile devices further comprises receive a notification from a user of completion of the plurality of images.

15. A computer system for constructing a model, the computer system comprising:
one or more computer processors;
one or more computer readable storage media; and
program instructions stored on the one or more computer readable storage media for execution by at least one of the one or more computer processors, the stored program instructions comprising instructions to:
receive a plurality of images of an asset from one or more mobile devices;
construct a 3D model of the asset from the plurality of images; and
determine whether the 3D model of the asset matches a digital twin record.

16. The computer system of claim 15, wherein determining whether the 3D model of the asset matches the digital twin record further comprises one or more of the following program instructions, stored on the one or more computer readable storage media, to:
receive a confirmation from a user that the asset matches the digital twin record; and
associate the 3D model of the asset with the digital twin record.

17. The computer system of claim 15, further comprising responsive to determining that the 3D model is incomplete, notify a user of the mobile device of one or more areas of the asset that require additional images.

18. The computer system of claim 15, wherein responsive to the 3D model of the asset does not match the digital twin record, create a new digital twin record for the 3D model.

19. The computer system of claim 15, further comprising utilize one or more photogrammetry techniques to construct the 3D model from the plurality of images.

20. The computer system of claim 15, wherein the 3D model is immutable.
